(19) United States
(12) Patent Application Publication
(10) Pub. No.: US 2026/0188226 A1
(43) Pub. Date: Jul. 2, 2026

(54) Subpixel Circuit and Display Device

(71) Applicant: LG Display Co., Ltd., Seoul (KR)

(72) Inventors: Sujin Jeon, Paju-si (KR); TaeKyeong Lee, Paju-si (KR)

(21) Appl. No.: 19/401,085

(22) Filed: Nov. 25, 2025

(30) Foreign Application Priority Data
Dec. 30, 2024 (KR) 10-2024-0200237

(51) Int. Cl. G09G 3/3233; G09G 3/32; G09G 3/3266; G09G 3/3291

(52) U.S. Cl. CPC G09G 3/3233; G09G 3/32; G09G 3/3266; G09G 3/3291; G09G 2300/043; G09G 2300/0819; G09G 2310/0267; G09G 2310/0275; G09G 2310/08; G09G 2330/021

(57) ABSTRACT

Embodiments of the present disclosure relate to a subpixel circuit and a display device capable of more accurately sampling the threshold voltage of a driving transistor. This is achieved by supplying a reference voltage to a lower gate node of the driving transistor during a sampling period in a non-emission period and electrically connecting the lower gate node of the driving transistor and a second node of the driving transistor during an emission period.

### CROSS-REFERENCE TO RELATED APPLICATION

The present application claims priority to Republic of Korea Patent Application No. 10-2024-0200237, filed on Dec. 30, 2024, which is hereby incorporated by reference in its entirety.

### BACKGROUND

### Field

Embodiments of the present disclosure relate to a subpixel circuit and a display device including the same.

### Discussion of Related Art

Representative display devices for displaying an image based on digital data include liquid crystal display (LCD) devices using liquid crystal and organic light emitting display devices using organic light emitting diodes (OLEDs).

Among the display devices, the organic light emitting display device uses self-luminous organic light emitting diodes, providing advantages, such as a fast response and better contrast ratio, luminous efficiency, luminance, and viewing angle.

Specifically, the organic light emitting display device may include organic light emitting diodes respectively provided in a plurality of subpixels disposed on a display panel and cause the organic light emitting diodes to emit light by controlling the voltage applied to the organic light emitting diodes, thereby displaying images while controlling the brightness of each subpixel.

A driving transistor is disposed in each of the plurality of subpixels in the display device to control the light emitting element, and the driving transistors respectively disposed in the plurality of subpixels may have different characteristics (e.g., threshold voltage, mobility, etc.) due to process deviation or deterioration over driving time, and in the display device, a luminance deviation may occur between each subpixel due to the characteristic deviation of the driving transistors in the subpixels.

Accordingly, efforts are being made to more effectively compensate for the characteristics of driving transistors.

### SUMMARY

Embodiments of the present disclosure may provide a subpixel circuit and a display device capable of more accurately sampling the threshold voltage of a driving transistor by controlling the voltage applied to the lower gate node of the driving transistor.

Embodiments of the present disclosure may provide a subpixel circuit and a display device capable of increasing the compensation range of the threshold voltage by sampling the threshold voltage of the negative voltage level of the driving transistor.

Embodiments of the present disclosure may provide a subpixel circuit and a display device capable of compensating for the threshold voltage of the driving transistor based on a sampling process that controls the voltage applied to the lower gate node of the driving transistor, thereby reducing panel stains and increasing resolution, and reducing power consumption.

Objects of embodiments of the present disclosure are not limited to those set forth herein, and other unmentioned objects would be apparent to one of ordinary skill in the art from the following description.

Embodiments of the present disclosure may provide a display device comprising a display panel where a plurality of subpixels, a plurality of gate lines, and a plurality of data lines are disposed, each of the plurality of subpixels including a driving transistor, a gate driving circuit configured to drive the plurality of gate lines, and a data driving circuit configured to supply a data voltage to the plurality of data lines.

Here, in at least one of the plurality of subpixels, a lower gate node of the driving transistor may be configured to be supplied with a reference voltage during a sampling period in a non-emission period, and the lower gate node of the driving transistor and a second node of the driving transistor may be configured to be electrically connected to each other during an emission period.

Embodiments of the present disclosure may provide a subpixel circuit comprising a driving transistor, a first transistor disposed between a lower gate node of the driving transistor and a second node of the driving transistor, a second transistor disposed between a reference voltage line supplying a reference voltage having a voltage level lower than a data voltage and a lower gate node of the driving transistor, a third transistor disposed between a high-potential voltage line supplying a high-potential voltage and a first node of the driving transistor, and a fourth transistor disposed between a data line supplying the data voltage and the second node of the driving transistor.

Embodiments of the disclosure may provide a display panel, comprising a plurality of subpixels, wherein at least one of the plurality of subpixels comprises a driving transistor; and a second transistor disposed between a reference voltage line supplying a reference voltage and the fourth node of the driving transistor; wherein the fourth node of the driving transistor is configured to be supplied with the reference voltage by turning on the second transistor.

According to one or more embodiments of the present disclosure, there may be provided a subpixel circuit and a display device capable of more accurately sampling the threshold voltage of a driving transistor by controlling the voltage applied to the lower gate node of the driving transistor.

According to one or more embodiments of the present disclosure, there may be provided a subpixel circuit and a display device capable of increasing the compensation range of the threshold voltage by sampling the threshold voltage of the negative voltage level of the driving transistor.

According to one or more embodiments of the present disclosure, there may be provided a subpixel circuit and a display device capable of compensating for the threshold voltage of the driving transistor based on a sampling process that controls the voltage applied to the lower gate node of the driving transistor, thereby reducing panel stains and increasing resolution, and reducing power consumption.

The effects of the present disclosure are not limited to the foregoing objects, and other effects will be apparent to one of ordinary skill in the art from the following detailed description.

### BRIEF DESCRIPTION OF THE DRAWINGS

The present disclosure will be more fully understood from the following detailed description and the accompanying drawings, which are provided for illustration only and are not intended to limit the present disclosure.

FIG. 1 is a view illustrating a display device according to one or more embodiments of the present disclosure.

FIG. 2 is a view illustrating an example of a subpixel according to one or more embodiments of the present disclosure.

FIGS. 3 and 4 are views illustrating characteristics according to a driving operation of a subpixel circuit according to one or more embodiments of the present disclosure.

FIG. 5 is a view illustrating, in further detail, characteristics according to a driving operation of a subpixel circuit according to one or more embodiments of the present disclosure.

FIG. 6 is a view illustrating an implementation example of a display device according to one or more embodiments of the present disclosure.

FIG. 7 is a view illustrating an example of a cross-sectional structure of a display panel according to one or more embodiments of the present disclosure.

FIGS. 8 and 9 are views illustrating, in further detail, a driving transistor in a subpixel circuit according to one or more embodiments of the present disclosure.

FIG. 10 is a view illustrating an implementation example of a gate driving circuit according to one or more embodiments of the present disclosure.

FIGS. 11 and 12 are views illustrating an implementation example of drivers in a gate driving circuit according to one or more embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “comprising”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure are described in detail with reference to the accompanying drawings.

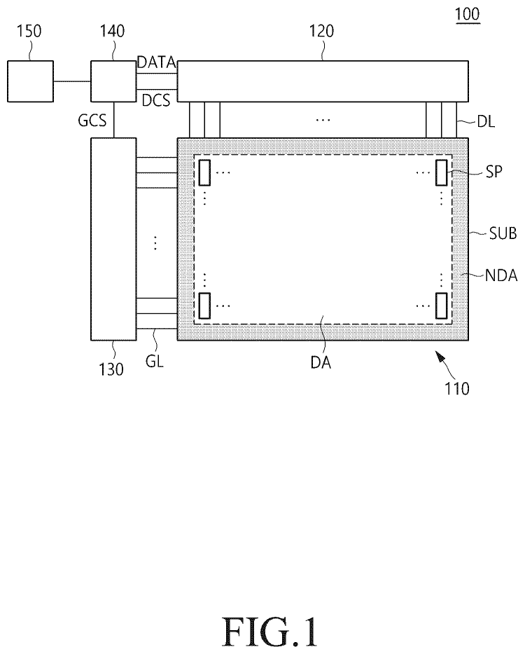

FIG. 1 is a view illustrating a display device 100 according to one or more embodiments of the present disclosure.

Referring to FIG. 1, according to one or more embodiments of the present disclosure, a display device 100 may include a display panel 110 and driving circuits for driving the display panel 110.

The driving circuits may include a data driving circuit 120 and a gate driving circuit 130. The display device 100 may further include a controller 140 controlling the data driving circuit 120 and the gate driving circuit 130.

The driving circuit may further include a power management integrated circuit that supplies various voltages or currents to the display panel 110, the data driving circuit 120, the gate driving circuit 130, and the controller 140 or controls various voltages or currents to be supplied.

The display panel 110 may include a plurality of subpixels SP connected to the plurality of data lines DL and the plurality of gate lines GL.

The display panel 110 may include a display area DA in which images are displayed and a non-display area NDA which is positioned outside of the display area DA and where no image is displayed. In the display panel 110, a plurality of subpixels SP for displaying images may be disposed in the display area DA, the data driving circuit 120, the gate driving circuit 130, and the controller 140 may be electrically connected or disposed in the non-display area NDA. Further, pad units for connection of integrated circuits or a printed circuit may be disposed in the non-display area NA.

The data driving circuit 120 is a circuit for driving the plurality of data lines DL, and may supply data signals to the plurality of data lines DL. The gate driving circuit 130 is a circuit for driving the plurality of gate lines GL, and may supply gate signals to the plurality of gate lines GL.

The gate driving circuit 130 may include at least one scan driver supplying gate signals to a plurality of gate lines GL and at least one emission control driver.

For example, the gate driving circuit 130 may include at least one first scan driver supplying a first scan gate signal, which is a type of gate signal, at least one second scan driver supplying a second scan gate signal, which is a type of gate signal, and at least one emission control driver supplying an emission control gate signal, which is a type of gate signal.

According to one or more embodiments, the gate driving circuit 130 may include a plurality of stages respectively corresponding to the plurality of gate lines GL, and each of the plurality of stages may include at least one of a first scan driver, a second scan driver, and an emission control driver.

The controller 140 may supply a data control signal DCS to the data driving circuit 120 to control the operation timing of the data driving circuit 120. The controller 140 may supply a gate control signal GCS for controlling the operation timing of the gate driving circuit 130 to the gate driving circuit 130.

The controller 140 may control to start a scan operation according to a timing implemented in each frame, convert input image data input from the outside (e.g., the host system 150) into image data DATA suited for the data signal format used in the data driving circuit 120, supply the image data DATA to the data driving circuit 120, and control data driving to proceed at an appropriate time according to the scan timing.

Specifically, the controller 140 may receive various timing signals, including a vertical synchronization signal VSYNC, a horizontal synchronization signal HSYNC, a data enable signal DE, and a clock signal CLK, along with the input image data, and generate various control signals DCS and GCS to control the data driving circuit 120 and the gate driving circuit 130 and output them to the data driving circuit 120 and the gate driving circuit 130.

The controller 140 may be implemented as a separate component from the data driving circuit 120, or the controller 140, along with the data driving circuit 120, may be implemented as an integrated circuit.

The data driving circuit 120 may receive the image data DATA from the controller 140 and supply data voltages to the plurality of data lines DL, thereby driving the plurality of data lines DL. Here, the data driving circuit 120 may be described as a source driving circuit.

The data driving circuit 120 may include one or more source driver integrated circuit SDIC.

For example, each source driver integrated circuit (SDIC) may be connected with the display panel 110 by a tape automated bonding (TAB) type or connected to a bonding pad of the display panel 110 by a chip on glass (COG) or chip on panel (COP) type or may be implemented by a chip on film (COF) type and connected with the display panel 110.

The gate driving circuit 130 may output a gate signal of a turn-on voltage level or a gate signal of a turn-off voltage level according to the control of the controller 140. The gate driving circuit 130 may sequentially drive the plurality of gate lines GL by sequentially supplying gate signals of the turn-on voltage level to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate in panel (GIP) type, in the non-display area NDA of the display panel 110. The gate driving circuit 130 may be disposed on the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type may be connected to the substrate SUB.

The gate driving circuit 130 may be composed of a plurality of stages, and when the gate driving circuit 130 is implemented in a gate-in-panel GIP type, each of the plurality of stages may be implemented as a plurality of GIP circuits.

At least one of the data driving circuit 120 and the gate driving circuit 130 may be disposed in the display area DA. For example, at least one of the data driving circuit 120 and the gate driving circuit 130 may be disposed not to overlap a plurality of subpixels SP or to overlap all or some of the plurality of subpixels SP.

When a specific gate line GL is opened by the gate driving circuit 130, the data driving circuit 120 may convert the image data DATA received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the driving scheme or the panel design scheme, gate driving circuits 130 may be connected with both the sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The display device 100 according to one or more embodiments of the present disclosure may be applied to wearable devices, such as smart watches. However, embodiments of the present disclosure are not limited thereto, and the display device may be applied in various forms to various product groups, such as monitors, laptop computers, vehicle displays, and mobile devices (e.g., smartphones or tablet PCs).

The display device 100 according to one or more embodiments of the present disclosure may be a display including a backlight unit, such as a liquid crystal display, or may be a self-emission display, such as an organic light emitting diode (OLED) display, a quantum dot display, or a micro light emitting diode (LED) display.

According to one or more embodiments of the present disclosure, when the display device 100 is an OLED display, each subpixel SP may include an organic light emitting diode (OLED), which is self-luminous, as a light emitting element. According to one or more embodiments of the present disclosure, when the display device 100 is a quantum dot display, each subpixel SP may include a light emitting element formed of a quantum dot, which is a self-luminous semiconductor crystal. If the display device 100 according to one or more embodiments of the present disclosure is a micro LED display, each subpixel SP may include a micro LED, which is self-emissive and formed of an inorganic material, as the light emitting element.

The display panel 110 according to one or more embodiments of the present disclosure may have a top emission structure or a bottom emission structure, and in some cases, may have a double-side emission structure.

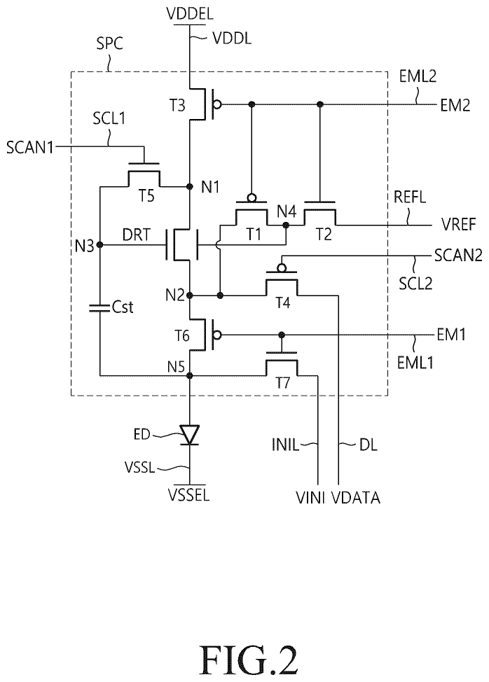

FIG. 2 is a view illustrating an example of a subpixel SP according to one or more embodiments of the present disclosure.

Referring to FIG. 2, each subpixel SP according to one or more embodiments of the present disclosure may include a light emitting element ED and a subpixel circuit SPC configured to drive the light emitting element ED.

The light emitting element ED may include a pixel electrode and a common electrode and may include a light emitting layer positioned between the pixel electrode and the common electrode.

The pixel electrode of the light emitting element ED may be an electrode disposed in each subpixel SP, and the common electrode may be an electrode commonly disposed in all the subpixels SP. Here, the pixel electrode may be an anode electrode, and the common electrode may be a cathode electrode. Conversely, the pixel electrode may be a cathode electrode, and the common electrode may be an anode electrode.

The common electrode of the light emitting element ED may be connected to a low-potential voltage line VSSL that applies a low-potential voltage VSSEL.

For example, the light emitting element ED may be an organic light emitting diode (OLED), a light emitting diode (LED), or a quantum dot light emitting element.

According to the example of FIG. 2, the subpixel circuit SPC may include a driving transistor DRT, first to seventh transistors T1 to T7, and a storage capacitor Cst.

The driving transistor DRT is a transistor for driving the light emitting element ED, and may include a first node N1, a second node N2, a third node N3, and a fourth node N4.

The first node N1 of the driving transistor DRT may be a drain node or a source node of the driving transistor DRT, and the second node N2 of the driving transistor DRT may be a source node or a drain node of the driving transistor DRT.

The third node N3 of the driving transistor DRT may be an upper gate node to which the upper gate electrode of the driving transistor DRT is connected, and the fourth node N4 of the driving transistor DRT may be a lower gate node to which the lower gate electrode of the driving transistor DRT is connected. For example, the lower gate electrode may be a body electrode of the driving transistor DRT.

According to the example of FIG. 2, the driving transistor DRT may be an n-type transistor, but embodiments of the present disclosure are not limited thereto, and the driving transistor DRT may be designed as a p-type transistor.

The first transistor T1 may be disposed between the fourth node N4 of the driving transistor DRT and the second node N2 of the driving transistor DRT, and the second transistor T2 may be disposed between the fourth node N4 of the driving transistor DRT and the reference voltage line REFL supplying a reference voltage VREF.

The first transistor T1 and the second transistor T2 may receive a second emission control gate signal EM2 from the gate driving circuit 130 through each gate node. Here, any one of the first transistor T1 and the second transistor T2 may be an n-type transistor, and the other transistor may be a p-type transistor.

According to the example of FIG. 2, the first transistor T1 may be a p-type transistor and the second transistor T2 may be an n-type transistor, but embodiments of the present disclosure are not limited thereto, and the first transistor T1 may be an n-type transistor and the second transistor T2 may be a p-type transistor.

In other words, the subpixel circuit SPC according to one or more embodiments of the present disclosure may reduce the number of second emission control gate lines EML2 by controlling the first transistor T1 and the second transistor T2 to be turned on at different timings using one gate signal (i.e., the second emission control gate signal EM2).

Specifically, the first transistor T1 may receive the second emission control gate signal EM2 of the turn-on voltage level from the gate driving circuit 130 through the second emission control gate line EML2 to control the connection between the fourth node N4 of the driving transistor DRT and the second node N2 of the driving transistor DRT. Here, the turn-on voltage level of the second emission control gate signal EM2 for turning on the first transistor T1 may be a low voltage level when the first transistor T1 is a p-type transistor.

Further, the second transistor T2 may receive the second emission control gate signal EM2 of the turn-on voltage level from the gate driving circuit 130 through the second emission control gate line EML2 to control the connection between the reference voltage line REFL supplying the reference voltage VREF and the fourth node N4 of the driving transistor DRT. Here, the turn-on voltage level of the second emission control gate signal EM2 for turning on the second transistor T2 may be a high voltage level when the second transistor T2 is an n-type transistor.

The reference voltage VREF may be a voltage applied to the fourth node N4 of the driving transistor DRT, i.e., the lower gate node, in order to positively shift the threshold voltage measurement value of the negative voltage level of the driving transistor DRT.

The reference voltage VREF may be designed to have a lower level than the data voltage VDATA supplied to the second node N2 of the driving transistor DRT through the data line DL, more smoothly positively shifting the threshold voltage measurement value of the negative voltage level.

According to one or more embodiments, the power management integrated circuit may output the reference voltage VREF having a level lower than that of the data voltage VDATA to the reference voltage line REFL.

For example, the power management integrated circuit may output a reference voltage VREF of a voltage level lower than a lower threshold voltage value in a preset data voltage setting range (i.e., a range from the lower threshold voltage value to an upper threshold voltage value) to the reference voltage line REFL.

Alternatively, the power management integrated circuit may receive information about the voltage level of the data voltage VDATA supplied to the data line DL from the controller 140, adaptively calculate the reference voltage VREF based on the received voltage level information and a preset offset voltage Voffset, and output the calculated reference voltage VREF to the reference voltage line REFL.

In a more specific example, the power management integrated circuit may derive the reference voltage (i.e., VREF=VDATA−Voffset) by calculating the difference between the data voltage VDATA and the offset voltage Voffset.

The third transistor T3 may be disposed between the high-potential voltage line VDDL supplying the high-potential voltage VDDEL and the first node N1 of the driving transistor DRT, and may receive the second emission control gate signal EM2 from the gate driving circuit 130 through the second emission control gate line EML2.

In other words, the switching operation may be controlled by receiving the same gate signal (i.e., the second emission control gate signal EM2) as the first transistor T1 and the second transistor T2.

For example, the third transistor T3 may be the same type of transistor (e.g., p-type transistor) as the first transistor T1. In other words, the first transistor T1 and the third transistor T3 may be turned on at the same timing.

The fourth transistor T4 may be disposed between the data line DL to which the data voltage VDATA is supplied and the second node N2 of the driving transistor DRT, and the fifth transistor T5 may be disposed between the first node of the driving transistor DRT and the third node N3 of the driving transistor.

The fourth transistor T4 may receive the second scan gate signal SCAN2 from the gate driving circuit 130 through the gate node, and the fifth transistor T5 may receive the first scan gate signal SCAN1 from the gate driving circuit 130 through the gate node.

According to the example of FIG. 2, the fourth transistor T4 may be a p-type transistor and the fifth transistor T5 may be an n-type transistor, but embodiments of the present disclosure are not limited thereto, and the fourth transistor T4 may be an n-type transistor or the fifth transistor T5 may be a p-type transistor.

Specifically, the fourth transistor T4 may receive the second scan gate signal SCAN2 of the turn-on voltage level from the gate driving circuit 130 through the second scan gate line SCL2 to control the connection between the data line DL and the second node N2 of the driving transistor DRT. Here, the turn-on voltage level of the second scan gate signal SCAN2 for turning on the fourth transistor T4 may be a low voltage level when the fourth transistor T4 is a p-type transistor.

Further, the fifth transistor T5 may receive the first scan gate signal SCAN1 of the turn-on voltage level from the gate driving circuit 130 through the first scan gate line SCL1 to control the connection between the first node N1 of the driving transistor DRT and the third node N3 of the driving transistor DRT. Here, the turn-on voltage level of the first scan gate signal SCAN1 for turning on the fifth transistor T5 may be a high voltage level when the fifth transistor T5 is an n-type transistor.

The sixth transistor T6 may be disposed between the fifth node N5 connected to the pixel electrode of the light emitting element ED and the second node N2 of the driving transistor DRT, and the seventh transistor T7 may be disposed between the fifth node N5 and the initialization voltage line INIL supplying the initialization voltage VINI.

The sixth transistor T6 and the seventh transistor T7 may receive the first emission control gate signal EM1 from the gate driving circuit 130 through each gate node. Any one of the sixth transistor T6 and the seventh transistor T7 may be an n-type transistor, and the other transistor may be a p-type transistor.

According to the example of FIG. 2, the sixth transistor T6 may be a p-type transistor and the seventh transistor T7 may be an n-type transistor, but embodiments of the present disclosure are not limited thereto, and the sixth transistor T6 may be an n-type transistor or the seventh transistor T7 may be a p-type transistor.

In other words, the subpixel circuit SPC according to one or more embodiments of the present disclosure may reduce the number of first emission control gate lines EML1 by controlling the sixth transistor T6 and the seventh transistor T7 to be turned on at different timings using one gate signal (i.e., the first emission control gate signal EM1).

Specifically, the sixth transistor T6 may receive the first emission control gate signal EM1 of the turn-on voltage level from the gate driving circuit 130 through the first emission control gate line EML1 to control the connection between the fifth node N5 and the second node N2 of the driving transistor DRT. Here, the turn-on voltage level of the first emission control gate signal EM1 for turning on the sixth transistor T6 may be a low voltage level when the sixth transistor T6 is a p-type transistor.

Further, the seventh transistor T7 may receive the first emission control gate signal EM1 of the turn-on voltage level from the gate driving circuit 130 through the first emission control gate line EML1 to control the connection between the fifth node N5 and the initialization voltage line INIL. Here, the turn-on voltage level of the first emission control gate signal EM1 for turning on the seventh transistor T7 may be a high voltage level when the seventh transistor T7 is an n-type transistor.

According to one or more embodiments, the first emission control gate signal EM1 and the second emission control gate signal EM2 may be emission control gate signals respectively output from the emission control drivers included in different stages in the gate driving circuit 130.

For example, when the subpixel SP illustrated in FIG. 2 is the nth subpixel connected to the nth stage (where n is a positive integer) in the gate driving circuit 130, the first emission control gate signal EM1 may be an emission control signal (i.e., EMn-2) provided from the emission control driver provided in the n-2th stage, and the second emission control gate signal EM2 may be an emission control signal (i.e., EMn) provided from the emission control driver provided in the nth stage.

According to the example of FIG. 2, the storage capacitor Cst may be disposed between the fifth node N5 and the third node N3 of the driving transistor DRT.

According to the example of FIG. 2, the driving transistor DRT, the second transistor T2, the fifth transistor T5, and the seventh transistor T7 may be oxide transistors, and the first transistor T1, the third transistor T3, the fourth transistor T4, and the sixth transistor T6 may be low-temperature polycrystalline silicon (LTPS) transistors.

However, embodiments of the present disclosure are not limited thereto, and at least one of the driving transistor DRT, the second transistor T2, the fifth transistor T5, and the seventh transistor T7 may be an LTPS transistor, and at least one of the first transistor T1, the third transistor T3, the fourth transistor T4, and the sixth transistor T6 may be an oxide transistor.

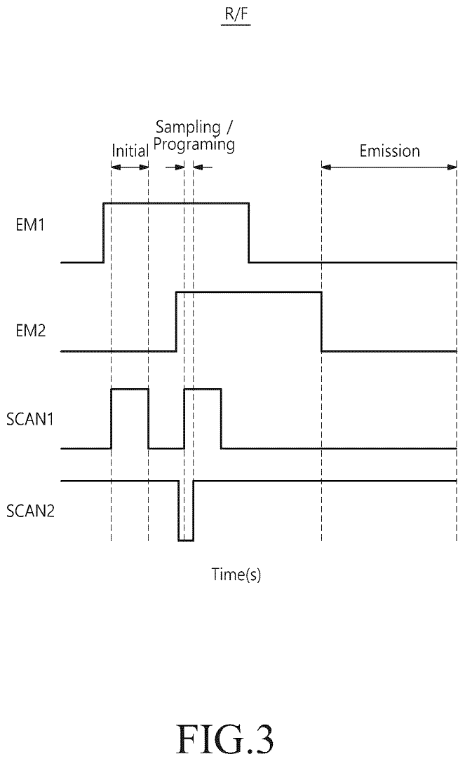

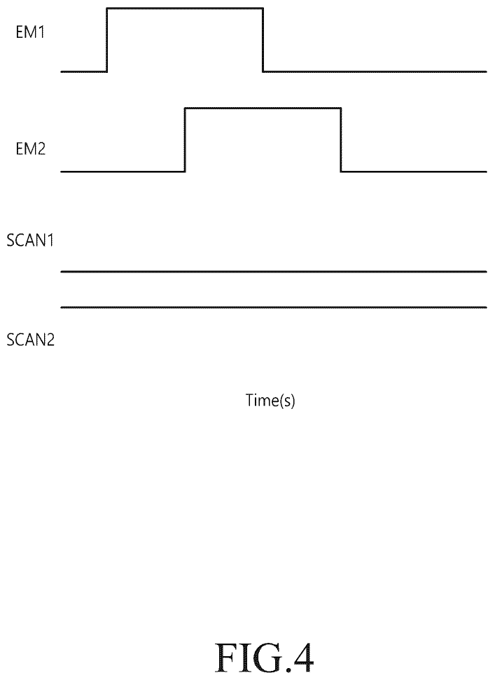

FIGS. 3 and 4 are views illustrating characteristics according to a driving operation of a subpixel circuit SPC according to one or more embodiments of the present disclosure.

Specifically, FIG. 3 illustrates a timing diagram in the refresh frame period R/F of the subpixel SP illustrated in FIG. 2, and FIG. 4 illustrates a timing diagram in the anode reset frame period A/F of the subpixel SP illustrated in FIG. 2.

Referring to FIGS. 3 and 4, the subpixel circuit SPC according to one or more embodiments of the present disclosure may be driven through a combination of at least one refresh frame period R/F and at least one anode reset frame period A/F in a single frame.

The refresh frame period R/F includes an emission period Emission and a non-emission period. The non-emission period may include an initialization period Initial, a sampling period Sampling, and a programming period Programming.

According to the example of FIG. 3, the sampling operation and the programming operation may be simultaneously performed in the display device 100 according to one or more embodiments of the present disclosure, but embodiments of the present disclosure are not limited thereto. Since the sampling operation and the programming operation may be simultaneously performed in the subpixel circuit SPC, both the sampling period Sampling and the programming period Programming can be collectively referred to as the sampling and programming period (Sampling & Programming) below.

According to the example of FIG. 3, the subpixel circuit SPC may receive the first emission control gate signal EM1, the first scan gate signal SCAN1, and the second scan gate signal SCAN2 of the high voltage level, and the second emission control gate signal EM2 of the low voltage level from the gate driving circuit 130 during the initialization period, turning on the first transistor T1, the third transistor T3, the fifth transistor T5, and the seventh transistor T7 and turning off the second transistor T2, the fourth transistor T4, and the sixth transistor T6.

Accordingly, the subpixel circuit SPC may initialize the fifth node N5 to which the pixel electrode of the light emitting element ED is connected to the initialization voltage VINI during the initialization period Initial.

The subpixel circuit SPC may receive the first emission control gate signal EM1, the second emission control gate signal EM2 and the first scan gate signal SCAN1 of the high voltage level, and the second scan gate signal SCAN2 of the low voltage level from the gate driving circuit 130 during the sampling and programming period Sampling & Programming, turning on the second transistor T2, the fourth transistor T4, the fifth transistor T5, and the seventh transistor T7 and turning off the first transistor T1, the third transistor T3, and the sixth transistor T6.

Accordingly, in the subpixel circuit SPC, the threshold voltage measurement value of the driving transistor DRT may be sampled and programmed based on the data voltage VDATA during the sampling and programming period Sampling & Programming. In other words, the sampling process and the programming process may be simultaneously performed in the subpixel circuit SPC.

Specifically, during the sampling and programming period Sampling & Programming, the fifth transistor T5 may be turned on, allowing the driving transistor DRT to be diode-connected. In this case, the gate voltage of the driving transistor DRT may be varied in response to the source potential of the driving transistor DRT, i.e., the data voltage VDATA, sampling the threshold voltage measurement value.

In the subpixel circuit SPC, the second transistor T2 may be turned on during the sampling and programming period Sampling & Programming, and thus the second reference voltage VREF2 may be supplied to the fourth node N4 of the driving transistor DRT, i.e., the lower gate node, thus positively shifting the threshold voltage measurement value of the negative voltage level of the driving transistor DRT.

The subpixel circuit SPC may receive the second scan gate signal SCAN2 of the high voltage level, and the first emission control gate signal EM1, the second emission control gate signal EM2, and the first scan gate signal SCAN1 of the low voltage level from the gate driving circuit 130 during the emission period Emission, turning on the first transistor T1, the third transistor T3, and the sixth transistor T6 and turning off the second transistor T2, the fourth transistor T4, the fifth transistor T5, and the seventh transistor T7.

Accordingly, the subpixel circuit SPC may allow the light emitting element ED to emit light by supplying a driving current to the light emitting element ED during the emission period.

In this case, in the subpixel circuit SPC, the first transistor T1 may be turned on during the emission period, and the fourth node N4 of the driving transistor DRT may be connected to the second node N2 (e.g., source contact) of the driving transistor, thereby changing the threshold voltage measurement value of the driving transistor DRT positively shifted in the sampling period Sampling, back to the threshold voltage measurement value of the negative voltage level.

According to the example of FIG. 4, the subpixel circuit SPC may receive the first scan gate signal SCAN1 of the low voltage level and the second scan gate signal SCAN2 of the high voltage level from the gate driving circuit 130 during the anode reset frame period A/F, turning off the fourth transistor T4 and the fifth transistor T5.

In the subpixel circuit SPC, during the anode reset frame period A/F, the second emission control signal EM2 of the high voltage level and the second emission control signal EM2 of the low voltage level may be supplied, controlling the switching operation of the first transistor T1, the second transistor T2, and the third transistor T3.

In the subpixel circuit SPC, during the anode reset frame period A/F, the first emission control signal EM1 of the high voltage level and the first emission control signal EM1 of the low voltage level may be supplied, controlling the switching operation of the sixth transistor T6 and the seventh transistor T7.

Accordingly, the subpixel circuit SPC may initialize the fifth node N5 connected to the pixel electrode of the light emitting element ED to the initialization voltage VINI during at least one period when the seventh transistor T7 is turned on in the anode reset frame period A/F.

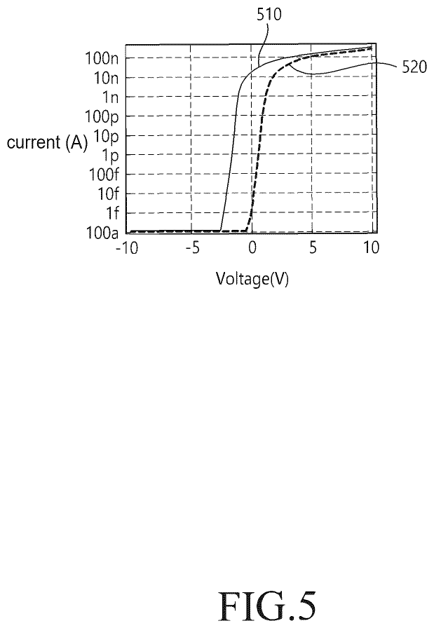

FIG. 5 is a view illustrating, in further detail, characteristics according to a driving operation of a subpixel circuit SPC according to one or more embodiments of the present disclosure.

Specifically, FIG. 5 illustrates a current-voltage characteristic curve I-V curve of the driving transistor DRT provided in the subpixel circuit SPC according to one or more embodiments of the present disclosure. The voltage may refer to the gate voltage (e.g., Vgs) of the driving transistor DRT.

Referring to FIG. 5, in the subpixel circuit SPC according to one or more embodiments of the present disclosure, the first transistor T1 may be turned off and the second transistor T2 may be turned on during the sampling period Sampling, so that the second reference voltage VREF2 may be supplied to the fourth node N4 of the driving transistor DRT, i.e., the lower gate node, thus positively shifting the threshold voltage measurement value of the negative voltage level of the driving transistor DRT from reference numeral 510 to reference numeral 520 of FIG. 5.

In other words, the display device 100 according to one or more embodiments of the present disclosure may sample the threshold voltage of the negative voltage level by controlling the voltage supplied to the lower gate node of the driving transistor DRT in the subpixel circuit SPC based on the diode-connection structure.

Thereafter, in the subpixel circuit SPC according to one or more embodiments of the present disclosure, the first transistor T1 may be turned on and the second transistor T2 may be turned off during the emission period, so that the fourth node N4 of the driving transistor DRT and the second node N2 (e.g., the source node) of the driving transistor may be connected to each other, returning the threshold voltage measurement value positively shifted in the sampling period Sampling to the original value (i.e., the threshold voltage measurement value of the negative voltage level) from reference numeral 520 to reference numeral 510 of FIG. 5.

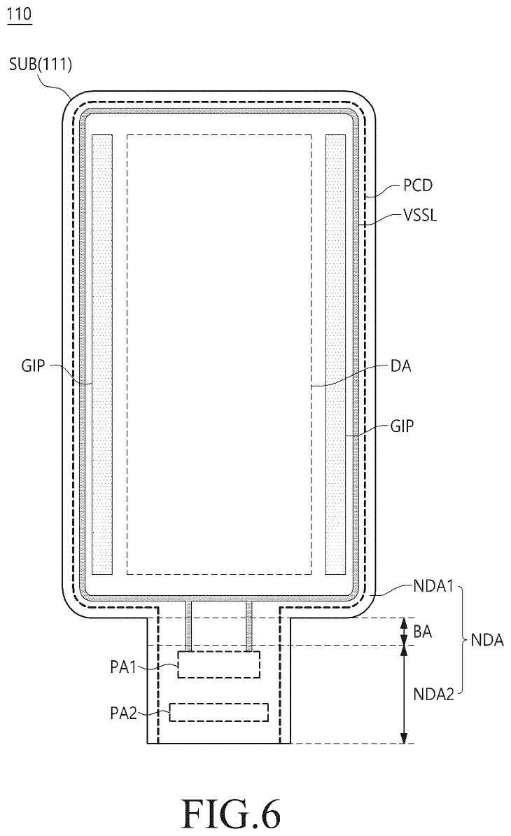

FIG. 6 is a view illustrating an implementation example of a display device 100 according to one or more embodiments of the present disclosure.

Referring to FIG. 6, the substrates (SUB) 111 of the display panel 110 according to one or more embodiments of the present disclosure may include a display area DA and a non-display area NDA.

At least one line and at least one electrode may be formed on the substrate 111. In the display device 100 according to one or more embodiments of the present disclosure, the substrate 111 may be a flexible substrate capable of bending. Here, “bending” may have a meaning equivalent to “folding” or “flexible.”

According to the example of FIG. 6, the non-display area NDA may include a first non-display area NDA1, a bending area BA, and a second non-display area NDA2.

The first non-display area NDA1 may be positioned around the display area DA, and may be an area closest to the display area DA among the first non-display area NDA1, the bending area BA, and the second non-display area NDA2. The first non-display area NDA1 may include a gate in panel (GIP) area where a GIP-type gate driving circuit is formed.

The second non-display area NDA2 may include pad areas PA1 and PA2 where various pads are disposed, and may be an area farthest from the display area DA among the first non-display area NDA1, the bending area BA, and the second non-display area NDA2.

The bending area BA is an area where the substrate 111 is bent, and may be an area positioned between the first non-display area NDA1 and the second non-display area NDA2.

For example, the gate in panel (GIP) area may be positioned in the left outer area and/or the right outer area of the display area DA. The non-display area NDA may be positioned in an upper outer area (or a lower outer area) of the display area DA. The second non-display area NDA2 may be an outer area than the bending area BA, and may include pad areas PA1 and PA2 to which circuit components such as a printed circuit board are electrically connected. For example, the first pad area PA1 may be an area where a driving circuit is bonded, and the second pad area PA2 may be an area where a printed circuit board is connected.

As described above, the substrate 111 may include a bending area BA that is bent and folded, and the bending area BA may be bent to be positioned on a lower surface of an unfolded portion. The bending area BA is a partial area of the non-display area NDA, and may be positioned in the driving circuit area to which the data driving circuit 120 is electrically connected and between the driving circuit area and the display area DA.

According to one or more embodiments, at least one of a high-potential voltage line VDDL, a low-potential voltage line VSSL, a first reference voltage line REFL1, a second reference voltage line REFL2, and a reset voltage line VARL may be disposed on the substrate 111 for driving the subpixel SP.

For example, a plurality of high-potential voltage lines VDDL may be disposed on the substrate 111 in the column (i.e., vertical) direction, but embodiments of the present disclosure are not limited thereto. According to one or more embodiments, a high-potential voltage pattern with which the plurality of high-potential voltage lines VDDL are integrated or electrically connected may be disposed in the non-display area NDA.

For example, the high-potential voltage line VDDL may be electrically connected to a data driving circuit or printed circuit board connected to the bending area BA and the pad areas PA1 and PA2 through the high-potential voltage pattern.

The low-potential voltage line VSSL may be disposed in the non-display area NDA to surround the outer area of the display area DA for efficient transfer of the low-potential voltage VSSEL. Further, the low-potential voltage line VSSL may be electrically connected to the data driving circuit 120 or the printed circuit board connected to the pad areas PA1 and PA2 through the bending area BA.

A crack prevention pattern PCD may be formed on the substrate 111. The crack prevention pattern PCD may be formed outside the low-potential voltage line VSSL disposed in the non-display area NDA, but the present disclosure is not limited thereto.

For example, the crack prevention pattern PCD is a pattern for preventing cracks of lines disposed on the substrate 111 and may be formed in a zigzag pattern, but the present disclosure is not limited thereto.

Specifically, when the bending area BA is bent, at least some of the lines passing through the bending area BA may be cracked to be electrically open or short-circuited with adjacent lines. In this case, an accurate signal may not be transferred through a line that is in an open state or a short-circuited state, and thus a problem with display driving or an image display may not be properly performed, and thus image quality may be greatly decreased. Thus, the crack prevention pattern PCD may be disposed on the substrate 111 according to one or more embodiments of the present disclosure.

The display device 100 according to one or more embodiments of the present disclosure may significantly reduce the bezel size in the display device 100 when the bending structure and the line arrangement structure illustrated in FIG. 6 are utilized, and an aesthetically satisfactory design may be provided through such a narrow bezel design.

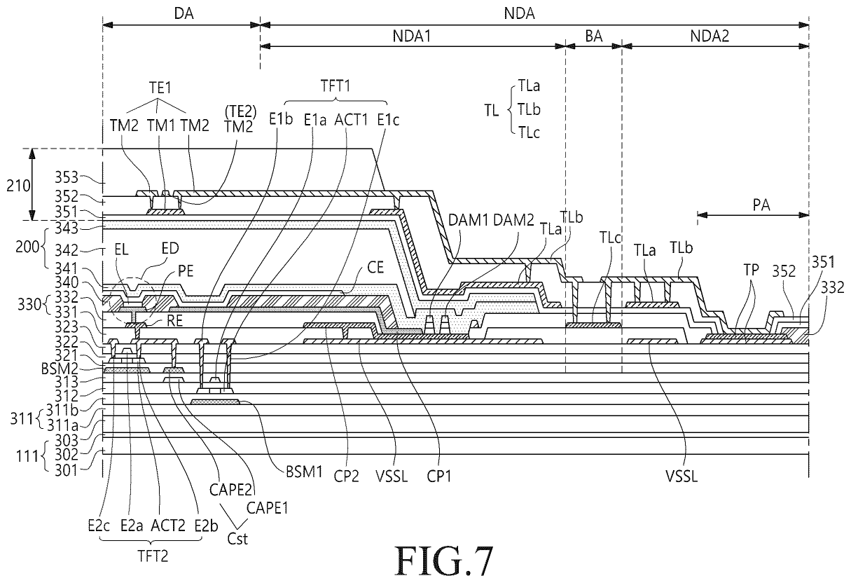

FIG. 7 is a view illustrating an example of a cross-sectional structure of a display panel 110 according to one or more embodiments of the present disclosure.

Referring to FIG. 7, the display panel 110 according to one or more embodiments of the present disclosure may include a substrate 111, a transistor unit, a light emitting element unit, and an encapsulation unit. However, FIG. 7 is merely an example of a cross-sectional structure of a display panel 110 according to one or more embodiments of the present disclosure, and embodiments of the present disclosure are not limited thereto.

According to the example of FIG. 7, the substrate 111 may be a single layer or multiple layers. When the substrate 111 includes multiple layers, the substrate 111 may include a first substrate 301, an intermediate substrate layer 302, and a second substrate 303. The intermediate substrate layer 302 may be positioned between the first substrate 301 and the second substrate 303.

For example, each of the first substrate 301 and the second substrate 303 may be a polyimide (PI) layer, and the intermediate substrate layer 302 may be an inorganic insulation layer, but embodiments of the present disclosure are not limited thereto.

When an electric charge is charged to the first substrate 301 which is a polyimide layer, the intermediate substrate layer 302 may prevent the electric charge from affecting transistors disposed on the second substrate 303 through the second substrate 303 which is a polyimide layer.

Further, the intermediate substrate layer 302 may prevent a moisture component from penetrating upward through the first substrate 301. For example, the intermediate substrate layer 302 may be formed of a single layer of silicon nitride (SiNx) or silicon oxide (SiOx) or multiple layers thereof, or may be formed of a double layer of silicon dioxide (SiO₂) and silicon nitride (SiNx), but embodiments of the present disclosure are not limited thereto.

The transistor unit may include insulation layers 311, 312, 313, 321, 322, and 323 on the substrate 111, thin film transistors TFT1 and TFT2, a storage capacitor CST, and various electrodes or signal lines.

The thin film transistors TFT1 and TFT2 included in the transistor unit may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be the gate electrode of the first thin film transistor TFT1, the second electrode E1b may be the source electrode or drain electrode of the first thin film transistor TFT1, and the third electrode E1c may be the drain electrode or source electrode of the first thin film transistor TFT1.

Hereinafter, for convenience of description, the first electrode E1a may be referred to as the first gate electrode E1a, the second electrode E1b as the first source electrode E1b, and the third electrode E1c as the first drain electrode E1c, but embodiments of the present disclosure are not limited thereto.

The first active layer ACT1 may include a first semiconductor material. For example, the first semiconductor material may include an oxide semiconductor, amorphous silicon, polysilicon, or low temperature polysilicon (LTPS), but embodiments of the present disclosure are not limited thereto. The first thin film transistor TFT1 may be implemented as a p-type transistor or an n-type thin film transistor.

The second thin film transistor TFT2 may include a second active layer ACT2, a fourth electrode E2a, a fifth electrode E2b, and a sixth electrode E2c.

The fourth electrode E2a may be the gate electrode of the second thin film transistor TFT2, the fifth electrode E2b may be the source electrode or drain electrode of the second thin film transistor TFT2, and the sixth electrode E2c may be the drain electrode or source electrode of the second thin film transistor TFT2.

Hereinafter, for convenience of description, the fourth electrode E2a may be referred to as a second gate electrode E2a, the fifth electrode E2b as a second source electrode E2b, and the sixth electrode E2c as a second drain electrode E2c.

The second active layer ACT2 may include a second semiconductor material. For example, the second semiconductor material may include an oxide semiconductor, amorphous silicon, polysilicon, or low temperature polysilicon (LTPS), but embodiments of the present disclosure are not limited thereto. The second thin film transistor TFT2 may be implemented as a p-type transistor or an n-type thin film transistor.

The type of the semiconductor material of each of the first active layer ACT1 of the first thin film transistor TFT1 and the second active layer ACT2 of the second thin film transistor TFT2 may be as follows.

Specifically, the first active layer ACT1 of the first thin film transistor TFT1 and the second active layer ACT2 of the second thin film transistor TFT2 may include an oxide semiconductor material. As another example, the first active layer ACT1 of the first thin film transistor TFT1 and the second active layer ACT2 of the second thin film transistor TFT2 may include a low-temperature polysilicon semiconductor material. As another example, the first active layer ACT1 of the first thin film transistor TFT1 may include a low-temperature polysilicon semiconductor material, and the second active layer ACT2 of the second thin film transistor TFT2 may include an oxide semiconductor material. As another example, the first active layer ACT1 of the first thin film transistor TFT1 may include an oxide semiconductor material, and the second active layer ACT2 of the second thin film transistor TFT2 may include a low-temperature polysilicon semiconductor material.

The purposes of the transistors in the display area DA may be as follows.

Specifically, all of the transistors in each subpixel SP may be implemented as first thin film transistors TFT1. As another example, all of the transistors in each subpixel SP may be implemented as second thin film transistors TFT2. As another example, some of all of the transistors in each subpixel SP may be implemented as first thin film transistors TFT1, and the others of the transistors may be implemented as second thin film transistors TFT2. In other words, each subpixel SP may include at least one first thin film transistor TFT1 and at least one second thin film transistor TFT2.

According to the example of FIG. 2, the first thin film transistor TFT1 may include at least one of the first transistor T1, the third transistor T3, the fourth transistor T4, and the sixth transistor T6, and the second thin film transistor TFT2 may include the seventh transistor T7, but embodiments of the present disclosure are not limited thereto.

According to the example of FIG. 2, the second transistor T2 and the fifth transistor T5 may be formed of the same material on the same plane as the seventh transistor T7, but embodiments of the present disclosure are not limited thereto.

In other words, each of the second transistor T2 and the fifth transistor T5 may include the second active layer ACT2, the second gate electrode E2a, the second source electrode E2b, and the second drain electrode E2c of the second thin film transistor TFT2.

The purposes of the transistors in the non-display area NDA may be as follows.

Specifically, the active layers of the transistors included in the gate-in-panel (GIP) type gate driving circuit may be formed of an oxide semiconductor material. As another example, the active layers of the transistors included in the gate-in-panel (GIP) type gate driving circuit may be formed of a low-temperature polysilicon semiconductor material. As another example, among the transistors included in the gate-in-panel (GIP) type gate driving circuit, some active layers may be formed of a low-temperature polysilicon semiconductor material, and other active layers may be formed of an oxide semiconductor material.

The second active layer ACT2 of the second thin film transistor TFT2 may be positioned higher from the substrate 111 than the first active layer ACT1 of the first thin film transistor TFT1.

The first buffer layer 311 may be disposed under the first active layer ACT1 of the first thin film transistor TFT1, and a second buffer layer 321 may be disposed under the second active layer ACT2 of the second thin film transistor TFT2. For example, the first active layer ACT1 of the first thin film transistor TFT1 may be positioned on the first buffer layer 311, and the second active layer ACT2 of the second thin film transistor TFT2 may be positioned on the second buffer layer 321. The second buffer layer 321 may be positioned higher than the first buffer layer 311.

The light emitting element portion may include a plurality of light emitting elements ED disposed on the planarization layer 330. Each of the plurality of light emitting elements ED may include a pixel electrode PE, a light emitting layer EL, and a common electrode CE.

The encapsulation unit may include an encapsulation layer 200 on the plurality of light emitting elements ED. The encapsulation layer 200 may be a single layer or multiple layers, but embodiments of the present disclosure are not limited thereto. In addition to the encapsulation layer 200, the encapsulation unit may further include at least one dam DAM for preventing a material constituting the encapsulation layer 200 from overflowing. In particular, when the second encapsulation layer 342 included in the encapsulation layer 200 is an organic encapsulation layer formed of an organic material, the dam DAM may prevent the organic material from overflowing.

Hereinafter, a structure or a vertical structure of the display panel 110 according to one or more embodiments of the present disclosure is described in more detail with reference to FIG. 7.

Referring to FIG. 7, the first buffer layer 311 may be disposed on the substrate 111. The first buffer layer 311 may be a single layer or multiple layers, but embodiments of the present disclosure are not limited thereto. When the first buffer layer 311 includes multiple layers, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel area in which a channel is formed, a source connection area on one side of the channel area, and a drain connection area on the other side of the channel area.

The first gate insulation layer 312 may be disposed on the first active layer ACT1 of the first thin film transistor TFT1. The first gate electrode E1a of the first thin film transistor TFT1 may be disposed on the first gate insulation layer 312. The first interlayer insulation layer 313 may be disposed on the first gate electrode E1a of the first thin film transistor TFT1. Here, the metal layer where the first gate electrode E1a of the first thin film transistor TFT1 is disposed may be referred to as a gate metal layer.

The second active layer ACT2 of the second thin film transistor TFT2 may be disposed on the second buffer layer 321. The second active layer ACT2 may include a channel area in which a channel is formed, a source connection area on one side of the channel area, and a drain connection area on the other side of the channel area.

The second gate insulation layer 322 may be disposed on the second active layer ACT2 of the second thin film transistor TFT2. The second gate electrode E2a of the second thin film transistor TFT2 may be disposed on the second gate insulation layer 322. The second interlayer insulation layer 323 may be disposed on the second gate electrode E2a of the second thin film transistor TFT2. Here, the second gate electrode E2a of the second thin film transistor TFT2 may be referred to as a second gate metal layer.

The first source electrode E1b and the first drain electrode E1c of the first thin film transistor TFT1, and the second source electrode E2b and the second drain electrode E2c of the second thin film transistor TFT2 may be disposed on the second interlayer insulation layer 323.

The first source electrode E1b and the first drain electrode E1c of the first thin film transistor TFT1 may be connected to the source connection area and the drain connection area, respectively, of the first active layer ACT1 through holes of the second interlayer insulation layer 323, the second gate insulation layer 322, the second buffer layer 321, the first interlayer insulation layer 313, and the first gate insulation layer 312.

The second source electrode E2b and the second drain electrode E2c of the second thin film transistor TFT2 may be connected to the source connection area and the drain connection area, respectively, of the second active layer ACT2 through the holes of the second interlayer insulation layer 323 and the second gate insulation layer 322.

The first source electrode E1b and the first drain electrode E1c of the first thin film transistor TFT1, and the second source electrode E2b and the second drain electrode E2c of the second thin film transistor TFT2 may include a first source-drain metal and may be disposed in the first source-drain metal layer.

The storage capacitor Cst may be formed by a first capacitor electrode CAPE1 and a second capacitor electrode CAPE2. According to one or more embodiments, the capacitor Cst may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110.

According to the example of FIG. 7, the first capacitor electrode CAPE1 may be disposed on the first gate insulation layer 312, and the second capacitor electrode CAPE2 may be disposed on the first interlayer insulation layer 313. For example, the first capacitor electrode CAPE1 may be formed of the same material as the first gate electrode E1a disposed on the same plane, but embodiments of the present disclosure are not limited thereto.

According to one or more embodiments, the first capacitor Ca in the subpixel SP may be formed by the first capacitor electrode CAPE1 disposed on the first gate insulation layer 312 and the second capacitor electrode CAPE2 disposed on the first interlayer insulation layer 313, such as the storage capacitor Cst.

However, embodiments of the present disclosure are not limited thereto, and the first capacitor Ca in the subpixel SP may be formed by a capacitor electrode which is formed of the same material as the second gate electrode E2a in the layer (i.e., the second gate insulation layer 322) where the second gate electrode E2A is disposed, and a capacitor electrode which is formed of the same material as the second source electrode E2b in the layer (i.e., the second interlayer insulation layer 323) where the second source electrode E2b is disposed.

The second source electrode E2b of the second thin film transistor TFT2 may be electrically connected to the second capacitor electrode CAPE2 through holes of the second interlayer insulation layer 323, the second gate insulation layer 322, and the second buffer layer 321.

Referring to FIG. 7, the transistor unit may further include a first shield pattern BSM1 disposed on the substrate 111. The first shield pattern BSM1 may overlap the first active layer ACT1 of the first thin film transistor TFT1. The first shield pattern BSM1 may be disposed under the first active layer ACT1 of the first thin film transistor TFT1.

According to the example of FIG. 7, the first shield pattern BSM1 may be disposed between the lower buffer layer 311a and the upper buffer layer 311b. For example, the first shield pattern BSM1 may be disposed on the lower buffer layer 311a, and be in the upper buffer layer 311b, as shown in FIG. 7. However, embodiments of the present disclosure are not limited thereto, and the first shield pattern BSM1 may be disposed between the substrate 111 and the first buffer layer 311.

The transistor unit may further include a second shield pattern BSM2 disposed on the substrate 111. The second shield pattern BSM2 may overlap the second active layer ACT2 of the second thin film transistor TFT2. The second shield pattern BSM2 may be disposed under the second active layer ACT2 of the second thin film transistor TFT2. For example, the second shield pattern BSM2 may be disposed between the first interlayer insulation layer 313 and the second buffer layer 321. In an example, the second shield pattern BSM2 may be disposed on the first interlayer insulation layer 313, and be in the second buffer layer 321, as shown in FIG. 7.

According to the example of FIG. 7, the second shield pattern BSM2 may be disposed on the first gate insulation layer 312, and may be formed of the same material as the second capacitor electrode CAPE2 on the same plane, but embodiments of the present disclosure are not limited thereto. As another example, the second shield pattern BSM2 may be formed of the same material as the first gate electrode E1a on the same plane as the first gate electrode E1a of the first thin film transistor TFT1.

The planarization layer 330 may be disposed on the first thin film transistor TFT1 and the second thin film transistor TFT2, and may be disposed under the light emitting element ED. The planarization layer 330 may be an organic insulation layer including an organic insulating material.

For example, the planarization layer 330 may be constituted of one layer. As another example, the planarization layer 330 may include two layers. The planarization layer 330 may include a first planarization layer 331 and a second planarization layer 332. As another example, the planarization layer 330 may include three or more layers. Embodiments of the present disclosure are not limited thereto.

According to the example of FIG. 7, the first planarization layer 331 may be disposed on the first source electrode E1b and the first drain electrode E1c of the first thin film transistor TFT1, and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed while covering both the first thin film transistor TFT1 and the second thin film transistor TFT2.

According to the example of FIG. 7, the connection electrode RE may be disposed on the first planarization layer 331. The connection electrode RE may electrically connect the second source electrode E2b of the second thin film transistor TFT2 and the pixel electrode PE.

The connection electrode RE may be electrically connected to the second source electrode E2b of the second thin film transistor TFT2 through the hole of the first planarization layer 331. The second source electrode E2b of the second thin film transistor TFT2 may be electrically connected to the second capacitor electrode CAPE2 of the storage capacitor Cst.

The connection electrode RE may be disposed in the second source-drain metal layer on the first planarization layer 331 and may include a second source-drain metal.

The second planarization layer 332 may be disposed on the connection electrode RE.

According to the example of FIG. 7, the light emitting element unit may be disposed on the second planarization layer 332. The light emitting element ED may be formed on the second planarization layer 332. The light emitting element ED may include a pixel electrode PE, a light emitting layer EL, and a common electrode CE. The emission area of the light emitting element ED may be formed in an area in which the pixel electrode PE, the light emitting layer EL, and the common electrode CE overlap and contact each other.

The pixel electrode PE may be disposed on the second planarization layer 332. The pixel electrode PE may be electrically connected to the connection electrode RE through the hole of the second planarization layer 332.

A bank 340 may be disposed on the pixel electrode PE. The opening of the bank 340 may expose a portion of the pixel electrode PE to form the emission area. The opening of the bank 340 may overlap a portion of the pixel electrode PE.

For example, the bank 340 may be formed of a material including a black pigment, or an organic material such as a benzocyclobutene resin, a polyimide resin, an acrylic resin, or a photosensitive polymer, but embodiments of the present disclosure are not limited thereto. When the bank 340 is formed of a material including a black pigment, a black dye, or the like, it may be a black bank. When the bank 340 is formed of a material including a black pigment or a black dye, light from the outside may be blocked or light reflected from the outside may be blocked, and thus the luminance of the display device 100 may be further enhanced.

The light emitting layer EL of the light emitting element ED may be disposed on a portion of the pixel electrode PE and the bank 340. The common electrode CE may be disposed on the light emitting layer EL.

According to the example of FIG. 7, the encapsulation unit may be disposed on the light emitting element unit and may be positioned on the common electrode CE. The encapsulation unit may include the encapsulation layer 200 formed on the common electrode CE.

The encapsulation layer 200 may prevent moisture or oxygen from penetrating into the light emitting element ED. For example, the encapsulation layer 200 may prevent moisture or oxygen from penetrating into the organic material included in the light emitting layer EL of the light emitting element ED. The encapsulation layer 200 may be formed of a single layer or multiple layers, but embodiments of the present disclosure are not limited thereto.

For example, the encapsulation layer 200 may include a first encapsulation layer 341, a second encapsulation layer 342, and a third encapsulation layer 343, but embodiments of the present disclosure are not limited thereto. For example, the first encapsulation layer 341 and the third encapsulation layer 343 may include an inorganic layer, and the second encapsulation layer 342 may include an organic layer, but embodiments of the present disclosure are not limited thereto.

The display panel 110 according to one or more embodiments of the present disclosure may have a built-in touch sensor. In this case, the display panel 110 according to one or more embodiments of the present disclosure may include a touch sensor layer 210 disposed on the encapsulation layer 200 and having a touch sensor.

According to the example of FIG. 7, the touch sensor layer 210 may include a plurality of touch electrodes TE corresponding to touch sensors, and may include at least one touch metal layer for forming the plurality of touch electrodes TE.

For example, the touch sensor layer 210 may include a first touch metal layer on which a plurality of first touch metals TM1 are disposed, and a second touch metal layer on which a plurality of second touch metals TM2 are disposed, to form the plurality of touch electrodes TE. In this case, the touch sensor layer 210 may further include a touch interlayer insulation layer 352 disposed between the first touch metal layer and the second touch metal layer.

For example, one of the first touch metal layer and the second touch metal layer may be a sensor metal layer and the other may be a bridge metal layer.

For example, the first touch metal layer may be a bridge metal layer, and the second touch metal layer may be a sensor metal layer. In this case, the plurality of second touch metals TM2 disposed in the second touch metal layer may be sensor metals forming touch sensors, and the plurality of first touch metals TM1 disposed in the first touch metal layer may be bridge metals electrically connecting the plurality of second touch metals TM2, which are sensor metals. For example, two or more second touch metals TM2 and at least one first touch metal TM1 may constitute one first touch electrode TE1. In this case, two or more second touch electrodes TE2 may be electrically connected by at least one first touch metal TM1.

As another example, the first touch metal layer may be a sensor metal layer, and the second touch metal layer may be a bridge metal layer. In this case, the plurality of first touch metals TM1 disposed in the first touch metal layer may be sensor metals forming touch sensors, and the plurality of second touch metals TM2 disposed in the second touch metal layer may be bridge metals electrically connecting the plurality of first touch metals TM1, which are sensor metals.

As another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this case, the plurality of first touch metals TM1 disposed in the first touch metal layer may include sensor metals and bridge metals, and the plurality of second touch metals TM2 disposed in the second touch metal layer may include sensor metals and bridge metals.

The touch sensor layer 210 may further include a touch buffer layer 351 disposed on the encapsulation layer 200. The touch buffer layer 351 may be disposed between the encapsulation layer 200 and the touch metal layer. For example, the touch buffer layer 351 may be disposed on the third encapsulation layer 343 of the encapsulation layer 200, as shown in FIG. 7. In an example, the first touch metal layer may be disposed on the touch buffer layer 351, and the touch interlayer insulation layer 352 may be disposed on the first touch metal layer.

The touch sensor layer 210 may further include a touch protection layer 353 disposed to cover the touch metal layer. For example, the touch protection layer 353 may be disposed on the second touch metal layer.

For example, the touch buffer layer 351 may be an inorganic layer including an inorganic insulating material or an organic layer including an organic insulating material, the touch interlayer insulation layer 352 may be an inorganic layer including an inorganic insulating material or an organic layer including an organic insulating material, and the touch protection layer 353 may be an inorganic layer including an inorganic insulating material or an organic layer including an organic insulating material.

For example, at least one of the touch buffer layer 351 and the touch interlayer insulation layer 352 may extend from the display area DA to the non-display area NDA. The touch protection layer 353 may be disposed to extend from the display area DA to the non-display area NDA. In one or more embodiments, the touch protection layer 353 may be disposed to extend from the display area DA to only the first non-display area NDA1 of the non-display area NDA, as shown in FIG. 7. However, embodiments of the disclosure are not limited thereto.

The touch routing line TL may electrically connect the touch electrode TE and the touch pad TP. The touch routing line TL may be formed of at least one of the first touch metal TM1 and the second touch metal TM2.

For example, the touch routing line TL may be formed of the first touch metal TM1, or the touch routing line TL may be formed of the second touch metal TM2, or the first touch metal TM1 and the second touch metal TM2. When one touch routing line TL is formed of the first touch metal TM1 and the second touch metal TM2, the first touch metal TM1 and the second touch metal TM2 constituting one touch routing line TL may be electrically connected through a hole in the touch interlayer insulation layer 352.

For example, one touch routing line TL may include a plurality of wiring sections, and each of the plurality of wiring sections may be a single wiring section or a double wiring section. Here, the single wiring section may be a wiring section having one signal path, and the double wiring section may be a wiring section where two signal paths are connected in parallel.

The touch routing line TL may be disposed along the inclined surface of the encapsulation layer 200, and may extend to the touch pad TP through the upper portion of the dam DAM1 and DAM2.

The touch buffer layer 351 may have an opening exposing at least a portion of the touch pad TP. The touch routing line TL may be electrically connected to the touch pad TP through the opening of the touch buffer layer 351. The touch interlayer insulation layer 352 may be disposed on the touch routing line TL, and may extend to an area where the touch pad TP is disposed. The touch protection layer 353 may be disposed only in the display area DA, or may extend to the non-display area NDA to be disposed on the touch routing line TL. In some cases, the touch protection layer 353 may further extend to the upper portion of the touch pad TP.

Each of the plurality of touch electrodes TE may be a mesh-type electrode having a plurality of openings. In this case, each of the plurality of touch electrodes TE may be formed of at least one second touch metal TM2. However, embodiments of the present disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected through at least one first touch metal TM1, which are bridge metals. For example, the two second touch metals TM2 spaced apart from each other may be electrically connected by the first touch metal TM1 to constitute one first touch electrode TE1.

According to the example of FIG. 7, the plurality of first touch metals TM1 and the plurality of second touch metals TM2 may be disposed not to overlap the light emitting element ED. The plurality of first touch metals TM1 and the plurality of second touch metals TM2 may overlap the bank 340. Accordingly, the luminous efficiency of the light emitting element ED may increase.

The touch routing line TL may connect the touch pad TP disposed in the pad area PA in the second non-display area NDA2 and the first touch electrode TE1 disposed in the display area DA. To that end, the touch routing line TL may be disposed across the second non-display area NDA2, the bending area BA, and the first non-display area NDA1.

The touch routing line TL may include a first line section TLa, a second line section TLb, and a third line section TLc. For example, the touch routing line TL may include the first line section TLa and the second line section TLb disposed in the first non-display area NDA1 and the second non-display area NDA2, and the third line section TLc disposed in the bending area BA. The third line section TLc may connect the first line section TLa and the second line section TLb.

The first line section TLa of the touch routing line TL is a single line section, and may further include a third touch metal layer where the third touch metal is disposed.

The first line section TLa of the touch routing line TL may extend along the inclined surface of the encapsulation layer 200 and may extend via the upper portion of at least one dam DAM1 or DAM2.

For example, the first line section TLa of the touch routing line TL may lead to the third line section TLc of the touch routing line TL through at least one of the first touch metal layer and the second touch metal layer.

The second line section TLb of the touch routing line TL may include at least one of a first touch metal layer where the first touch metal TM1 is disposed and a second touch metal layer where the second touch metal TM2 is disposed.

For example, the second line section TLb of the touch routing line TL may be formed of a second touch metal layer. As another example, the second line section TLb of the touch routing line TL may be configured by electrically connecting the first touch metal layer and the second touch metal layer.

For example, the second line section TLb of the touch routing line TL may be electrically connected to the touch pad TP through a contact hole (opening) that penetrates the second planarization layer 332, the touch buffer layer 351, and the touch interlayer insulation layer 352.

For example, the third line section TLc of the touch routing line TL may lead to the second line section TLb of the touch routing line TL.

The third line section TLc of the touch routing line TL may include a metal layer different from the first to third touch metal layers where the first and second touch metals TM1 and TM2 are disposed. For example, the metal layer included in the third line section TLc of the touch routing line TL may be the same as the metal layer where the electrode or line for display driving is disposed. For example, the metal layer included in the third line section TLc of the touch routing line TL may include a metal layer where the pixel electrode PE is disposed, but the present disclosure is not limited thereto.

The touch pad TP is electrically connected to the second line section TLb of the touch routing line TL, and may include a metal layer different from the first to third touch metal layers. For example, the metal layer included in the touch pad TP may be the same as the metal layer where the electrode or line for display driving is disposed. For example, the metal layer included in the touch pad TP may include a metal layer where the pixel electrode PE is disposed, but the present disclosure is not limited thereto.

According to the example of FIG. 7, the display panel 110 according to one or more embodiments of the present disclosure may further include a low-potential voltage line VSSL to which the low-potential voltage VSSEL which is a common voltage is applied and a connection pattern for connecting the common electrode CE and the low-potential voltage line VSSL.

For example, the connection pattern may include a first connection pattern CP1 and a second connection pattern CP2.

For example, the first connection pattern CP1 may connect the common electrode CE and the second connection pattern CP2, and the second connection pattern CP2 may connect the first connection pattern CP1 and the common voltage line VSSL, but embodiments of the present disclosure are not limited thereto.

For example, the first connection pattern CP1 may include the same material as that of the pixel electrode PE. The second connection pattern CP2 may include the same material as the connection electrode RE.

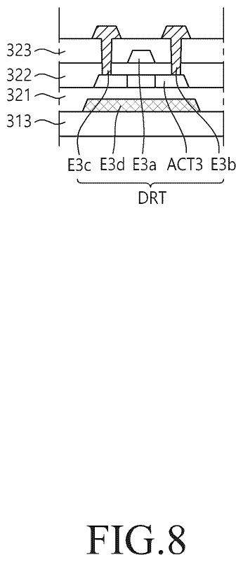

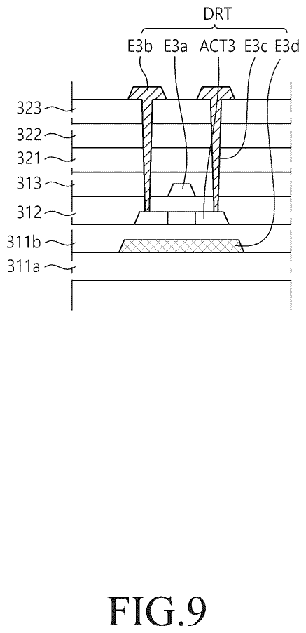

FIGS. 8 and 9 are views illustrating, in further detail, a driving transistor DRT in a subpixel circuit SPC according to one or more embodiments of the present disclosure.

Specifically, FIG. 8 illustrates a cross-sectional structure according to an example of a driving transistor DRT provided in a subpixel circuit SPC according to one or more embodiments of the present disclosure, and FIG. 9 illustrates a cross-sectional structure according to another example of the driving transistor DRT.

Referring to FIGS. 8 and 9, a driving transistor DRT according to one or more embodiments of the present disclosure may include a third active layer ACT3, a seventh electrode E3a, an eighth electrode E3b, a ninth electrode E3c, and a tenth electrode E3d.

The seventh electrode E3a may be an upper gate electrode of the driving transistor DRT, the eighth electrode E3b may be a drain electrode or a source electrode of the driving transistor DRT, the ninth electrode E3c may be a source electrode or a drain electrode of the driving transistor DRT, and the tenth electrode E3d may be a lower gate electrode of the driving transistor DRT. For example, the lower gate electrode may be a body electrode.

Hereinafter, for convenience of description, the seventh electrode E3a may be described as the upper gate electrode E3a, the eighth electrode E3b may be described as the third source electrode E3b, the ninth electrode E3c may be described as the third drain electrode E3c, and the tenth electrode E3d may be described as the lower gate electrode E3d, but embodiments of the present disclosure are not limited thereto.

The third active layer ACT3 may include a third semiconductor material. For example, the third semiconductor material may include an oxide semiconductor, amorphous silicon, polysilicon, or low-temperature polysilicon LTPS, but embodiments of the present disclosure are not limited thereto. The driving transistor DRT may be implemented as a p-type transistor or an n-type transistor.

According to the example of FIG. 8, the lower gate electrode E3d of the driving transistor DRT may be disposed on the first interlayer insulation layer 313, the third active layer ACT3 may be disposed on the second buffer layer 321, the upper gate electrode E3a may be disposed on the second gate insulation layer 322, and the third source electrode E3b and the third drain electrode E3c may be disposed on the second interlayer insulation layer 323.

In this case, the lower gate electrode E3d may be formed of the same material as the second shield pattern BSM2, the upper gate electrode E3a may be formed of the same material as the second gate electrode E2a, and the third source electrode E3b and the third drain electrode E3c may be formed of the same material as at least one of the first source electrode E1b, the first drain electrode E1c, the second source electrode E2b and the second drain electrode E2c, but embodiments of the present disclosure are not limited thereto.

As illustrated in FIG. 9, the lower gate electrode E3d of the driving transistor DRT may be disposed on the lower buffer layer 311a, and the upper buffer layer 311b covers the lower gate electrode E3d. The third active layer ACT3 may be disposed on the upper buffer layer 311b, the upper gate electrode E3a may be disposed on the first gate insulation layer 312, and the third source electrode E3b and the third drain electrode E3c may be disposed on the second interlayer insulation layer 323.

In this case, the lower gate electrode E3d may be formed of the same material as the first shield pattern BSM1, the upper gate electrode E3a may be formed of the same material as the first gate electrode E1a, and the third source electrode E3b and the third drain electrode E3c may be formed of the same material as at least one of the first source electrode E1b, the first drain electrode E1c, the second source electrode E2b and the second drain electrode E2c, but embodiments of the present disclosure are not limited thereto.

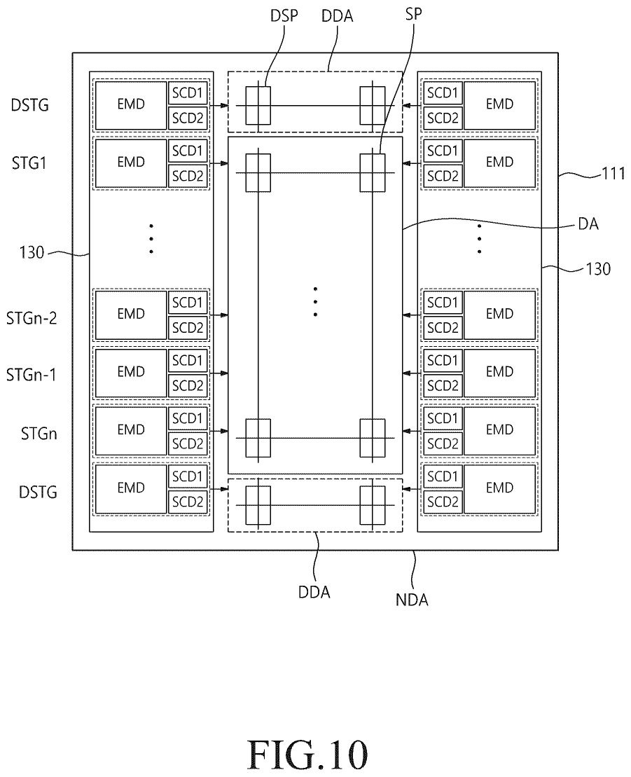

FIG. 10 is a view illustrating an implementation example of a gate driving circuit 130 according to one or more embodiments of the present disclosure.

Referring to FIG. 10, the gate driving circuit 130 may include a plurality of GIP circuits. The plurality of GIP circuits may be disposed in the non-display area NDA to respectively correspond to the plurality of stages STG.

For example, the plurality of GIP circuits may include a GIP circuit disposed in the left non-display area NDA and a GIP circuit disposed in the right non-display area NDA with respect to the display area DA corresponding to each of the plurality of stages STG, but embodiments of the present disclosure are not limited thereto, and the GIP circuit may be disposed only in the non-display area NDA corresponding to either the left or right side of the display area DA.

Each of the plurality of GIP circuits GIPC may include at least one driver among a first scan driver SCD1, a second scan driver SCD2, and an emission control driver EMD.

According to the example of FIG. 10, as the GIP disposed in each of the left and right non-display areas NDA, the first scan driver SCD1 and the second scan driver SCD2 may be disposed in an area close to the display area DA, and the emission control driver EMD may be disposed in an area far from the display area DA.

The drivers provided in each of the plurality of GIP circuits may have the same area. However, embodiments of the present disclosure are not limited thereto, and at least two or more of the first scan driver SCD1, the second scan driver SCD2, and the emission control driver EMD provided in each of the plurality of GIP circuits may be designed to have different areas.

According to the examples of FIGS. 2 and 10, the first scan driver SCD1 provided in the nth stage STGn (where n is an integer of 4 or more) may supply a first scan gate signal SCAN1 to the nth subpixel connected to the nth stage STGn through the first scan gate line SCL1, the second scan driver SCD2 provided in the nth stage STGn may provide a second scan gate signal SCAN2 to the nth subpixel connected to the nth stage STGn through the second scan gate line SCL2, and the emission control driver EMD provided in the nth stage STGn may supply a second emission control gate signal EM2 to the nth subpixel connected to the nth stage STGn through the second emission control gate line EML2.

Meanwhile, the emission control driver EMD provided in the n-2th stage STGn-2 may supply a first emission control gate signal EM1 to the nth subpixel connected to the n-2th stage STGn-2 through the first emission control gate line EML1.

According to one or more embodiments, at least one dummy stage DSTG connected to at least one dummy subpixel DSP disposed in the dummy display area DDA may be disposed in each of the upper and lower areas of the plurality of stages STG1 to STGn.

For example, the dummy subpixel DSP disposed in the dummy display area DDA is designed to have the same structure as the subpixel SP disposed in the display area DA, and the light emitting element ED may not be disposed.

In a more specific example, the dummy subpixel DSP may include a subpixel circuit SPC including a driving transistor DRT, first to seventh transistors T1 to T7, and a storage capacitor Cst, as illustrated in FIG. 2.

In FIG. 10, only one dummy stage DSTG is illustrated in each of the upper area of the first stage STG1 and the lower area of the nth stage STGn, but embodiments of the present disclosure are not limited thereto, and two or more dummy stages DSTG may be disposed in each of the upper area of the first stage STG1 and the lower area of the nth stage STGn.

According to the example of FIG. 10, as the GIPs disposed in the left and right non-display areas NDA corresponding to each of the dummy stage DSTG, the first scan driver SCD1 and the second scan driver SCD2 may be disposed in an area close to the display area DA, and the emission control driver EMD may be disposed in an area far from the display area DA.

According to one or more embodiments, the upper area of the first stage STG1 may include a first dummy stage disposed in an upper portion of the first stage STG1, i.e., an area close to the first stage STG1, and a second dummy stage disposed in an upper portion of the first dummy stage, i.e., an area far from the first stage STG1.

Here, the emission control driver EMD provided in the second dummy stage may supply a first emission control gate signal EM1 to the first subpixel connected to the second dummy stage through the first emission control gate line EML1.

Here, the first subpixel may be at least one subpixel receiving the first scan gate signal SCAN1, the second scan gate signal SCAN2, and the second emission control gate signal EM2 from the first stage STG1.

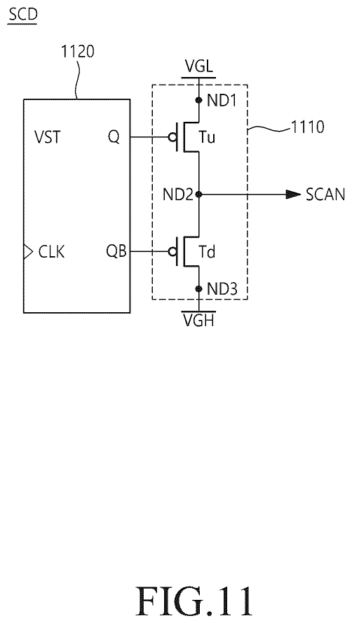

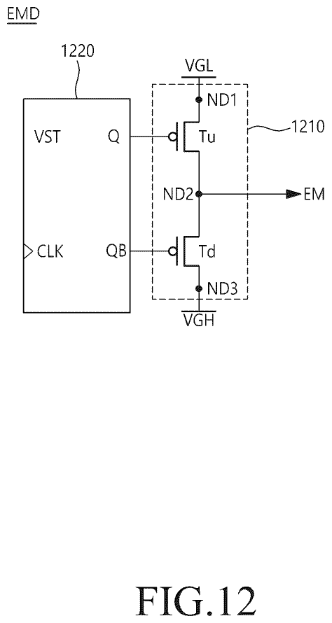

FIGS. 11 and 12 are views illustrating an implementation example of drivers SCD and EMD in a gate driving circuit 130 according to one or more embodiments of the present disclosure.

Specifically, FIG. 11 illustrates the scan driver SCD according to an example, provided in the gate driving circuit 130 according to one or more embodiments of the present disclosure, and FIG. 12 illustrates the emission control driver EMD according to an example, provided in the gate driving circuit 130 according to one or more embodiments of the present disclosure.

Specifically, the scan driver SCD may include at least one of a first scan driver SCD1 and a second scan driver SCD2.

Referring to FIGS. 11 and 12, the scan driver SCD and the emission control driver EMD may include buffer circuits 1110 and 1210 and control circuits 1120 and 1220, respectively.

Each of the buffer circuits 1110 and 1210 may include a pull-up transistor Tu connected between the first node ND1 and the second node ND2, and a pull-down transistor TD connected between the third node ND3 and the second node ND2.

Each of the control circuits 1120 and 1220 may control the voltage of a first control node (i.e., a Q node) that is the gate node of the pull-up transistor Tu and a second control node (i.e., a QB node) that is the gate node of the pull-down transistor TD.

Each of the buffer circuits 1110 and 1210 may output a gate signal to a gate line GL electrically connected to the second node ND2.

Specifically, the buffer circuit 1110 of the first scan driver SCD1 may output a first scan gate signal SCAN1 to the first scan gate line SCL1, and the buffer circuit 1110 of the second scan driver SCD2 may output a second scan gate signal SCAN2 to the second scan gate line SCL2.

Further, the buffer circuit 1210 of the emission control driver EMD may output an emission control gate signal EM to at least one of the first emission control gate line EML1 and the second emission control gate line EML2.

In each of the buffer circuits 1110 and 1210, a first power voltage may be applied to the first node ND1, and a second power voltage may be applied to the third node ND3. Any one of the first power voltage and the second power voltage may be a gate high voltage VGH, and the other voltage may be a gate low voltage VGL having a voltage level lower than that of the gate high voltage VGH.

According to the examples of FIGS. 11 and 12, the pull-up transistor Tu and the pull-down transistor Td provided in each of the buffer circuits 1110 and 1210 of the scan driver SCD and the emission control driver EMD may be p-type transistors.

When the pull-up transistor Tu and the pull-down transistor Td provided in each of the buffer circuits 1110 and 1210 are p-type transistors, the first power voltage may be the gate low voltage VGL and the second power voltage may be the gate high voltage VGH.

However, embodiments of the present disclosure are not limited thereto, and the pull-up transistor Tu and the pull-down transistor Td provided in each of the buffer circuits 1110 and 1210 of the scan driver SCD and the emission control driver EMD may be designed as n-type transistors.

When the pull-up transistor Tu and the pull-down transistor Td provided in each of the buffer circuits 1110 and 1210 are n-type transistors, the first power voltage may be the gate high voltage VGH and the second power voltage may be the gate low voltage VGL.

According to one or more embodiments, each of the buffer circuit 1110 of the scan driver SCD and the buffer circuit 1210 of the emission control driver EMD may receive a first power voltage and a second power voltage having different voltage levels.

For example, the buffer circuit 1110 of the scan driver SCD may output the scan gate signal SCAN based on the first gate high voltage and the first gate low voltage, and the emission control driver EMD may output the emission control gate signal EM based on the second gate high voltage and the second gate low voltage.

According to the examples of FIGS. 11 and 12, in the scan driver SCD and the emission control driver EMD, the start signal VST and the clock signal CLK corresponding to each driver may be supplied from the controller 140, and the gate high voltage VGH and the gate low voltage VGL may be supplied to the pull-up transistor Tu which is turned on or off according to the voltage of the Q node and the pull-down transistor Td which is turned on or off according to the voltage of the QB node from the power management integrated circuit, so that the scan gate signal SCAN and the emission control gate signal EM may be output.

For example, the clock signals CLK respectively supplied to the first scan driver SCD1, the second scan driver SCD2, and the emission control driver EMD may be the same signal.

Alternatively, at least two clock signals among the clock signals CLK respectively supplied to the first scan driver SCD1, the second scan driver SCD2, and the emission control driver EMD may be different signals.

In a more specific example, the first scan driver SCD1 may receive a first clock signal, the second scan driver SCD2 may receive a second clock signal, the emission control driver EMD may receive a third clock signal, where at least two of the first to third clock signals may be different signals.

The first scan driver SCD1, the second scan driver SCD2, and the emission control driver EMD may be synchronized with the edges of the clocks corresponding to the respective drivers, so that the voltage of the output signal is changed to the voltage of the start signal VST. Thus, the output signal may be generated in a waveform having the same phase as the start signal VST. If the waveform of the start signal VST is changed, the waveform of the output signal may also be changed accordingly, and the input signal may overlap the output signal.

A display device according to one or more embodiments of the present disclosure may be described as follows.

A display device according to one or more embodiments of the present disclosure may comprise a display panel in which a plurality of subpixels, a plurality of gate lines, and a plurality of data lines are disposed, each of the plurality of subpixels including a driving transistor, a gate driving circuit configured to drive the plurality of gate lines, and a data driving circuit configured to supply a data voltage to the plurality of data lines.

In at least one of the plurality of subpixels, a lower gate node of the driving transistor is configured to be supplied with a reference voltage during a sampling period in a non-emission period, and the lower gate node of the driving transistor and a second node of the driving transistor are configured to be electrically connected to each other during an emission period.

Each of the plurality of subpixels may further include a first transistor disposed between the lower gate node of the driving transistor and a second node of the driving transistor, and a second transistor disposed between the lower gate node of the driving transistor and a reference voltage line supplying the reference voltage.

One of the first transistor and the second transistor may be an n-type transistor, and the other transistor may be a p-type transistor.

The gate driving circuit is configured to supply a second emission control gate signal to each of a gate node of the first transistor and a gate node of the second transistor.

The first transistor is configured to be turned on during an emission period to electrically connect the lower gate node of the driving transistor and the second node of the driving transistor.

The second transistor is configured to be turned on during the sampling period to supply the reference voltage to the lower gate node of the driving transistor.

Each of the plurality of subpixels may further include a third transistor disposed between a high-potential voltage line supplying a high-potential voltage and a first node of the driving transistor.

The gate driving circuit is configured to supply a second emission control gate signal to a gate node of the third transistor, which is the same type of transistor as the first transistor.

Each of the plurality of subpixels may further include a fourth transistor disposed between the second node of the driving transistor and any one corresponding data line among the plurality of data lines, and a fifth transistor disposed between a first node of the driving transistor and an upper gate node of the driving transistor.

The gate driving circuit is configured to supply a second scan gate signal to a gate node of the fourth transistor and is configured to supply a first scan gate signal to a gate node of the fifth transistor.

Each of the plurality of subpixels may further include a sixth transistor disposed between the second node of the driving transistor and a light emitting element, and a seventh transistor disposed between an initialization voltage line supplying an initialization voltage and the light emitting element.

Any one of the sixth transistor and the seventh transistor may be an n-type transistor, and the other transistor may be a p-type transistor.

The gate driving circuit is configured to supply a first emission control gate signal to each of a gate node of the sixth transistor and a gate node of the seventh transistor.

The seventh transistor is configured to be turned on during the sampling period in the non-emission period to supply the initialization voltage to a pixel electrode of the light emitting element.

The reference voltage may be a voltage having a lower voltage level than the data voltage.

Each of the plurality of subpixels may include a storage capacitor disposed between the upper gate node of the driving transistor and a light emitting element.

A subpixel circuit according to one or more embodiments of the present disclosure may comprise a driving transistor, a first transistor disposed between a lower gate node of the driving transistor and a second node of the driving transistor, a second transistor disposed between a reference voltage line supplying a reference voltage having a voltage level lower than a data voltage and a lower gate node of the driving transistor, a third transistor disposed between a high-potential voltage line supplying a high-potential voltage and a first node of the driving transistor, and a fourth transistor disposed between a data line supplying the data voltage and the second node of the driving transistor.

A display panel according to embodiments of the disclosure may comprise a plurality of subpixels, wherein at least one of the plurality of subpixels comprises a driving transistor; and a second transistor disposed between a reference voltage line supplying a reference voltage and the fourth node of the driving transistor; wherein the fourth node of the driving transistor is configured to be supplied with the reference voltage by turning on the second transistor in a non-emission period.

The fourth node of the driving transistor may be a lower gate node to which the lower gate electrode of the driving transistor is connected, and the lower gate node of the driving transistor may be configured to be supplied with the reference voltage by turning on the second transistor during a sampling period in a non-emission period, the reference voltage having a voltage level lower than a data voltage.

The at least one subpixel may further comprise a first transistor disposed between a second node of the driving transistor and a fourth node of the driving transistor. The lower gate node of the driving transistor and the second node of the driving transistor may be electrically connected to each other during an emission period by turning on the first transistor.

The at least one subpixel may further comprise: a third transistor disposed between a high-potential voltage line supplying a high-potential voltage and a first node of the driving transistor; a fourth transistor disposed between a data line supplying the data voltage and the second node of the driving transistor; a fifth transistor disposed between the first node of the driving transistor and an upper gate node of the driving transistor; a sixth transistor disposed between the second node of the driving transistor and a light emitting element; and a seventh transistor disposed between an initialization voltage line supplying an initialization voltage and the light emitting element.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device, comprising:
a display panel in which a plurality of subpixels, a plurality of gate lines, and a plurality of data lines are disposed, each of the plurality of subpixels including a driving transistor;
wherein in at least one of the plurality of subpixels:
a lower gate node of the driving transistor is configured to be supplied with a reference voltage during a sampling period in a non-emission period, and
the lower gate node of the driving transistor and a second node of the driving transistor are configured to be electrically connected to each other during an emission period.

2. The display device of claim 1, wherein each of the plurality of subpixels further includes:
a first transistor disposed between the lower gate node of the driving transistor and the second node of the driving transistor; and
a second transistor disposed between the lower gate node of the driving transistor and a reference voltage line supplying the reference voltage.

3. The display device of claim 2, wherein one of the first transistor and the second transistor is an n-type transistor, and another one of the first transistor and the second transistor is a p-type transistor.

4. The display device of claim 2, further comprising:
a gate driving circuit configured to drive the plurality of gate lines; and
a data driving circuit configured to supply a data voltage to the plurality of data lines,
wherein the gate driving circuit is configured to supply a second emission control gate signal to each of a gate node of the first transistor and a gate node of the second transistor.

5. The display device of claim 2, wherein the first transistor is configured to be turned on during the emission period to electrically connect the lower gate node of the driving transistor and the second node of the driving transistor.

6. The display device of claim 2, wherein the second transistor is configured to be turned on during the sampling period to supply the reference voltage to the lower gate node of the driving transistor.

7. The display device of claim 4, wherein each of the plurality of subpixels further includes a third transistor disposed between a high-potential voltage line supplying a high-potential voltage and a first node of the driving transistor,
wherein the gate driving circuit is configured to supply a second emission control gate signal to a gate node of a sixth transistor, and
wherein the third transistor is a same type of transistor as the first transistor.

8. The display device of claim 4, wherein each of the plurality of subpixels further includes:
a fourth transistor disposed between the second node of the driving transistor and a corresponding data line among the plurality of data lines; and
a fifth transistor disposed between a first node of the driving transistor and an upper gate node of the driving transistor.

9. The display device of claim 8, wherein the gate driving circuit is configured to supply a second scan gate signal to a gate node of a fourth transistor, and wherein the gate driving circuit is further configured to supply a first scan gate signal to a gate node of a fifth transistor.

10. The display device of claim 1, wherein each of the plurality of subpixels further includes:
a sixth transistor disposed between the second node of the driving transistor and a light emitting element; and
a seventh transistor disposed between an initialization voltage line supplying an initialization voltage and the light emitting element.

11. The display device of claim 10, wherein any one of the sixth transistor and the seventh transistor is an n-type transistor, and another one of the sixth transistor and the seventh transistor is a p-type transistor.

12. The display device of claim 10, further comprising a gate driving circuit configured to supply a first emission control gate signal to each of a gate node of the sixth transistor and a gate node of the seventh transistor.

13. The display device of claim 10, wherein the seventh transistor is configured to be turned on during the sampling period in the non-emission period to supply the initialization voltage to a pixel electrode of the light emitting element.

14. The display device of claim 1, wherein the reference voltage is a voltage having a lower voltage level than a data voltage supplied to the plurality of data lines.

15. The display device of claim 1, wherein each of the plurality of subpixels further includes a storage capacitor disposed between an upper gate node of the driving transistor and a light emitting element.

16. A subpixel circuit, comprising:
a driving transistor;
a first transistor disposed between a lower gate node of the driving transistor and a second node of the driving transistor;
a second transistor disposed between a reference voltage line supplying a reference voltage and a lower gate node of the driving transistor, the reference voltage having a voltage level lower than a data voltage;
a third transistor disposed between a high-potential voltage line supplying a high-potential voltage and a first node of the driving transistor; and
a fourth transistor disposed between a data line supplying the data voltage and the second node of the driving transistor.

17. A display panel, comprising:
a plurality of subpixels, wherein at least one of the plurality of subpixels comprises:
a driving transistor; and
a second transistor disposed between a reference voltage line supplying a reference voltage and a fourth node of the driving transistor;
wherein the fourth node of the driving transistor is configured to be supplied with the reference voltage by turning on the second transistor in a non-emission period.

18. The display panel of claim 17, wherein:
the fourth node of the driving transistor is a lower gate node to which a lower gate node of the driving transistor is connected, and
the lower gate node of the driving transistor is configured to be supplied with the reference voltage by turning on the second transistor during a sampling period in the non-emission period, the reference voltage having a voltage level lower than a data voltage.

19. The display panel of claim 18, wherein at least one subpixel further comprises a first transistor disposed between a second node of the driving transistor and the fourth node of the driving transistor, and
wherein the lower gate node of the driving transistor and the second node of the driving transistor are electrically connected to each other during an emission period by turning on the first transistor.

20. The display panel of claim 19, wherein the at least one subpixel further comprises:
a third transistor disposed between a high-potential voltage line supplying a high-potential voltage and a first node of the driving transistor;
a fourth transistor disposed between a data line supplying the data voltage and the second node of the driving transistor;
a fifth transistor disposed between the first node of the driving transistor and an upper gate node of the driving transistor;
a sixth transistor disposed between the second node of the driving transistor and a light emitting element; and
a seventh transistor disposed between an initialization voltage line supplying an initialization voltage and the light emitting element.
